(19) United States
(12) Patent Application Publication
(10) Pub. No.: US 2014/0000844 A1
(43) Pub. Date: Jan. 2, 2014

(54) ELECTRONICS CASE WITH INCLUDED HEAT DIFFUSER

(71) Applicant: KITARU INNOVATIONS INC., Lascelles (BB)

(72) Inventor: Kapoor Chandaria, Nairobi (KE)

(73) Assignee: KITARU INNOVATIONS INC., Lascelles (BB)

(21) Appl. No.: 13/788,352

(22) Filed: Mar. 7, 2013

Related U.S. Application Data
(60) Provisional application No. 61/666,285, filed on Jun. 29, 2012.

(51) Int. Cl. H05K 7/20

(52) U.S. Cl. CPC H05K 7/2039
USPC 165/80.2

(57) ABSTRACT

A protective case for a planar electronic device such as a tablet or smartphone. The case includes a back having an interior surface and an exterior surface; an opening defined in the exterior surface; and a pocket defined between the interior and exterior surfaces. The case further includes a heat dissipating assembly disposed adjacent the opening. This assembly draws heat from the electronic device and transmits that heat to the air surrounding the case. The case may also include a front which is connected to the back via a spine. The spine allows the front and back to be positioned one on top of the other. A flap may also cover the opening in the back and be movable between open and closed positions. Preferably, the heat dissipating assembly includes a copper sheet that is retained within a sleeve that is inserted into the pocket in the back,

### CROSS-REFERENCE TO RELATED APPLICATION

This application claims priority from U.S. Provisional Application Ser. No. 61/666,285, filed Jun. 29, 2012, the disclosure of which is incorporated herein by reference.

### BACKGROUND OF THE INVENTION

1. Technical Field

This invention relates generally to electronic equipment. More particularly, this invention relates to a protective case for electronic equipment such as planar tablet computing devices or smart phones. Specifically, this invention is directed to a protective case for electronic devices which includes a heat dissipating assembly for removing heat generated by the electronic device from the protective case.

2. Background Information

One of the problems experienced by users of personal tablet type computing devices is that these devices tend to generate a substantial amount of heat during operation. In order for the device to operate properly, it is necessary that heat generated by the device be able to escape therefrom in order to keep the operating temperature at a safe level. Many people using these devices have started to place them in cases to protect them from impacts. While these cases may protect the electronic devices from damage due to impact and may aid in preventing damage to the screens thereof, there is a problem in that the cases tend to capture heat generated by the device during operation. This is especially problematic in particular brands of tablet type computing devices. The heat build-up may, over time, ultimately cause d complete failure of the electronic device.

There is therefor a need in the art for an improved protective cover that reduces the possibility of heat build-up damage to electronic devices placed therein.

### BRIEF SUMMARY OF THE INVENTION

The device of the present invention is a protective case for an electronic device such as a tablet or smartphone. The case includes a back having an interior surface and an exterior surface; an opening defined in the exterior surface; and a pocket defined between the interior and exterior surfaces. The case further includes a heat dissipating assembly disposed adjacent the opening. This assembly draws heat from the electronic device and transmits that heat to the air surrounding the case. The case may also include a front which is connected to the back via a spine. The spine allows the front and back to be positioned one on top of the other. A flap may also cover the opening in the back and be movable between open and closed positions. Preferably, the heat dissipating assembly includes a copper sheet that is retained within a sleeve that is inserted into the pocket in the back.

The heat dissipation assembly preferably further includes a plurality of apertures defined within the sleeve that surrounds the copper sheet. Additionally, apertures may be defined in the back and these apertures preferably are aligned with the apertures in the sleeve.

In a second embodiment of the invention the heat dissipation assembly includes a band of heat conductive material which extends through an opening in the back and is disposed adjacent an exterior surface of the back. Preferably two bands of copper are positioned partially within the pocket of the case and partially adjacent the exterior surface of the back. Heat from the electronic device is transferred to those regions of the copper bands that lie within the pocket and the heat so transferred travels along the copper bands to the portions thereof that lie adjacent the exterior surface. The heat in the portions of the copper bands outside the case is transmitted to the surrounding air.

In a third embodiment of the invention the flap and back also include apertures which align with apertures in the sleeve. Heat generated by the electronic device is transferred through the air in the pocket to the heat dissipation member. The heat dissipation member then transmits the heat to the air in the aligned apertures in the sleeve, back and flap, and thereby to the air surrounding the case. Heat is transferred to the surrounding air by the heat dissipation member via conduction, radiation, and to a lesser extent by convection (through the air in the aligned apertures being heated and then transferring the heat to the surrounding air).

### BRIEF DESCRIPTION OF THE SEVERAL VIEWS OF THE DRAWINGS

A preferred embodiment of the invention, illustrated of the best mode in which Applicant contemplates applying the principles, is set forth in the following description and is shown in the drawings and is particularly and distinctly pointed out and set forth in the appended claims.

FIG. 1 is a front perspective view of a protective case for an electronics device in accordance with the present invention shown in an open position so that the electronic device retained therein is visible;

FIG. 2 is a side perspective view of the protective case shown in an open position with the electronics device being partially inserted or withdrawn from the pocket 33;

FIG. 3 is a perspective view of the heat dissipation assembly shown alone and removed from the protective case;

FIG. 4 is a front view of the protective case in an open position with the electronics device retained therein;

FIG. 5 is a front view of the protective case in an open position with the electronics device removed therefrom;

FIG. 6 is a rear view of the protective case in an open position and with a back flap in a closed position;

FIG. 7 is a longitudinal cross-section of the protective device taken along line 7-7 of FIG. 4;

FIG. 8 is a lateral cross-section of the protective device taken along line 8-8 of FIG. 4;

FIG. 9 is a rear perspective view of the protective case shown in a closed position with the back flap moved to an open position;

FIG. 10 is a rear perspective view of a second embodiment of a protective case in accordance with the present invention, shown in a closed position with a back flap closed and heat dissipation bands extending through the back cover; and

FIG. 11 is a rear perspective view of a third embodiment of a protective case in accordance with the present invention, shown in a closed position without a back flap present and showing a plurality of heat dissipation apertures defined in the back cover.

Similar numbers refer to similar parts throughout the drawings.

### DETAILED DESCRIPTION OF THE INVENTION

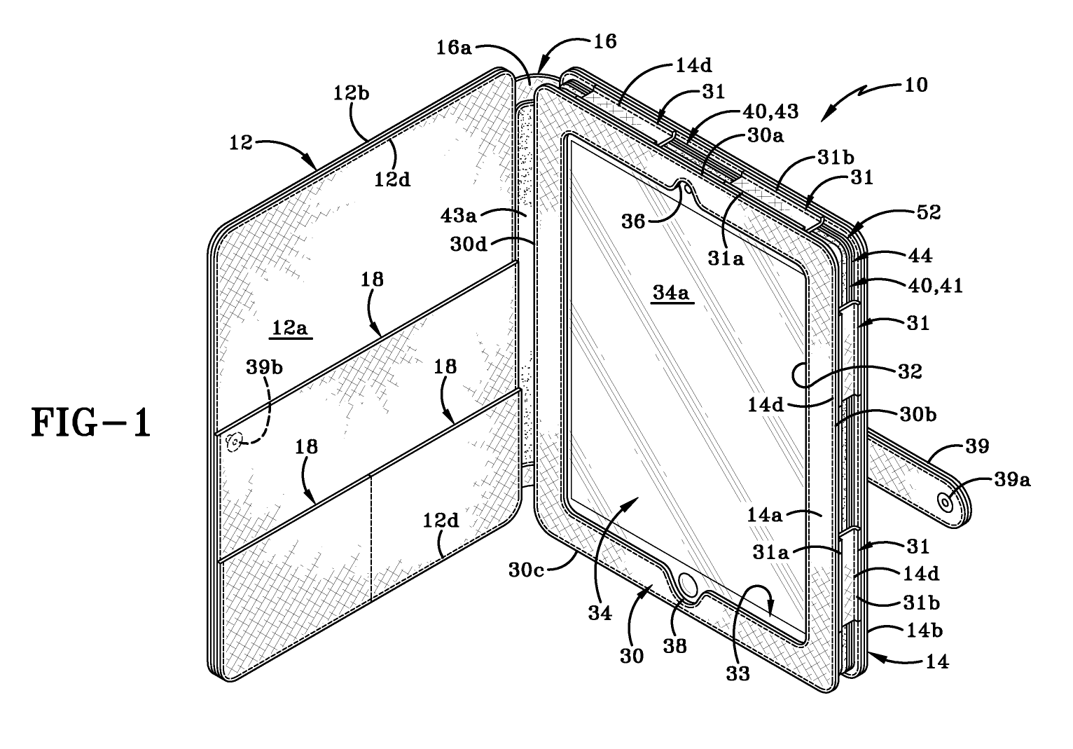

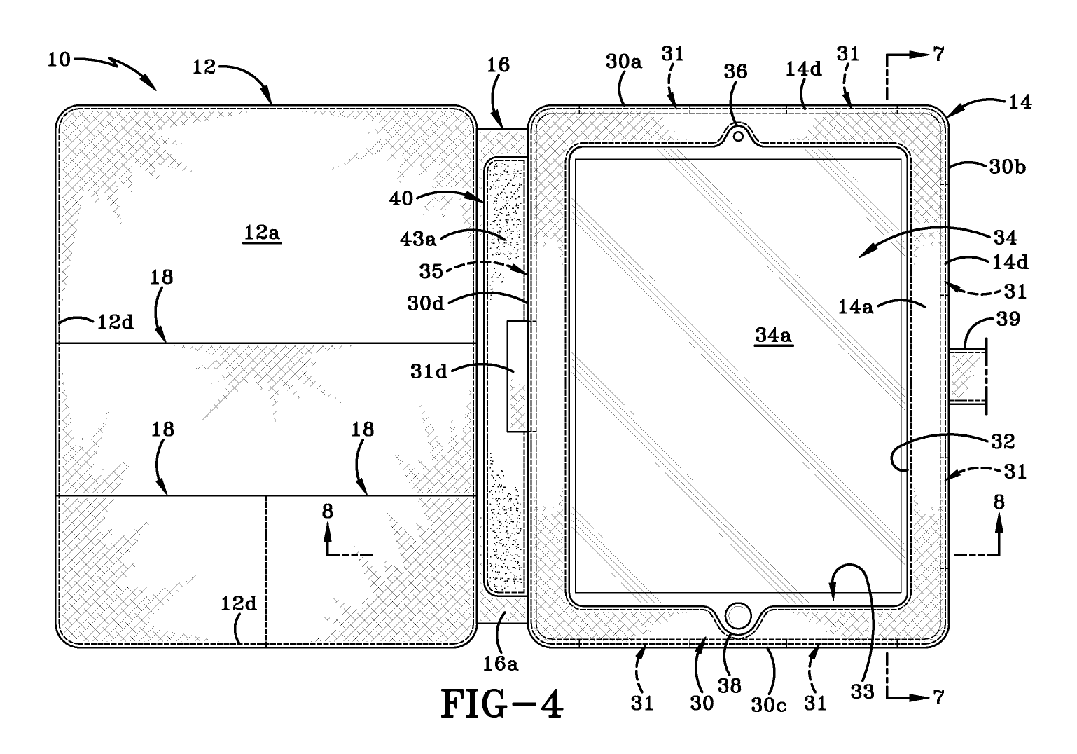

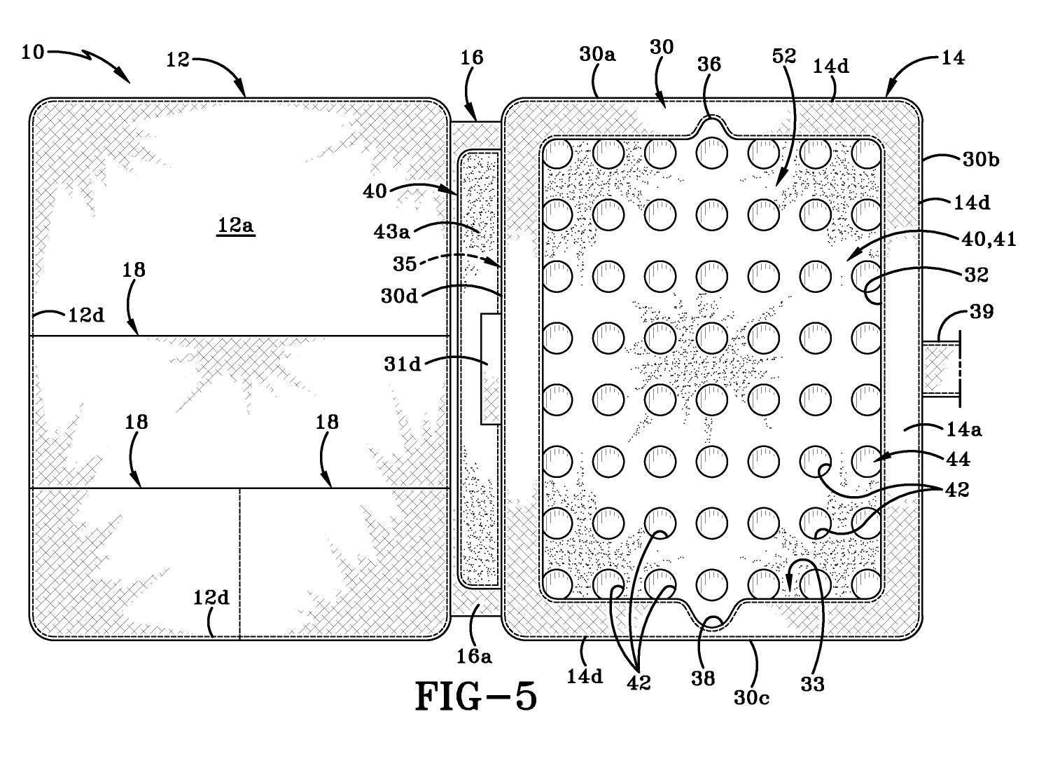

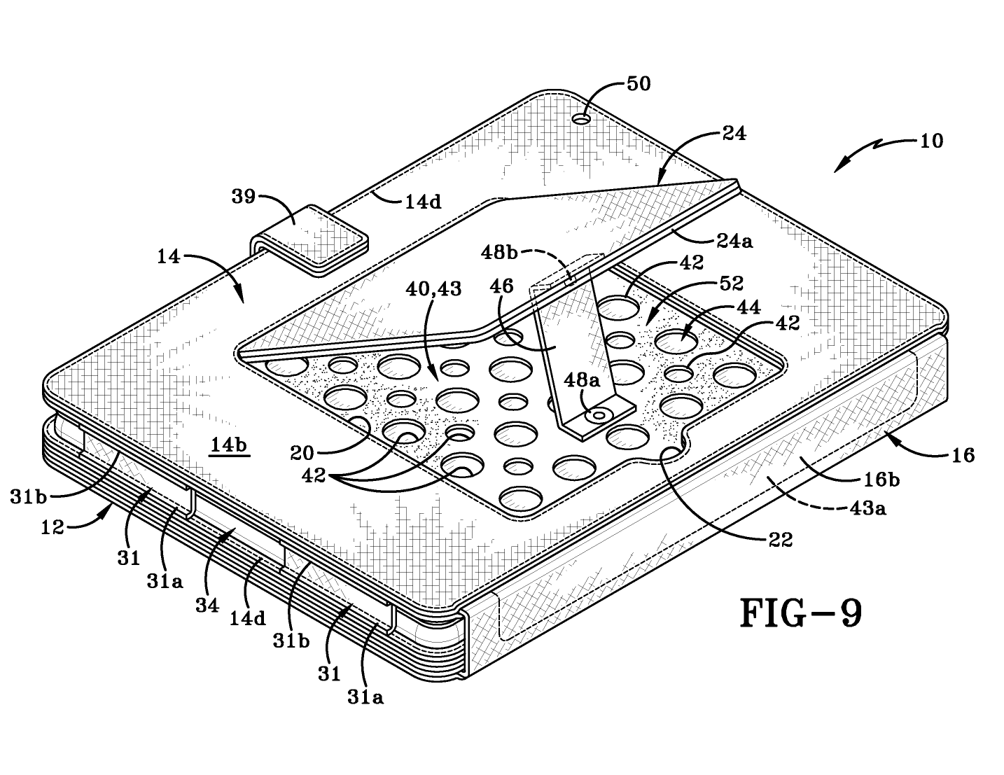

Referring to FIGS. 1-8 there is shown a protective case for an electronic device in accordance with the present invention, generally indicated by the reference number 10. Case 10 includes a front 12, a back 14, and a spine 16 disposed between front 12 and back 14. Front 12 includes an interior layer 12a and an exterior layer 12b. Back 14 has an interior layer 14a and an exterior layer 14b. Spine 16 has an interior surface 16a and an exterior surface 16b (FIG. 6). Spine 16 folds to enable interior layers 12a, 14a of front 12 and back 14 to be positioned adjacent each other so that the overall case 10 has the appearance of a book, as may be seen in FIG. 9. Case 10 is movable between an open position (FIG. 1) and a closed position (FIG. 9).

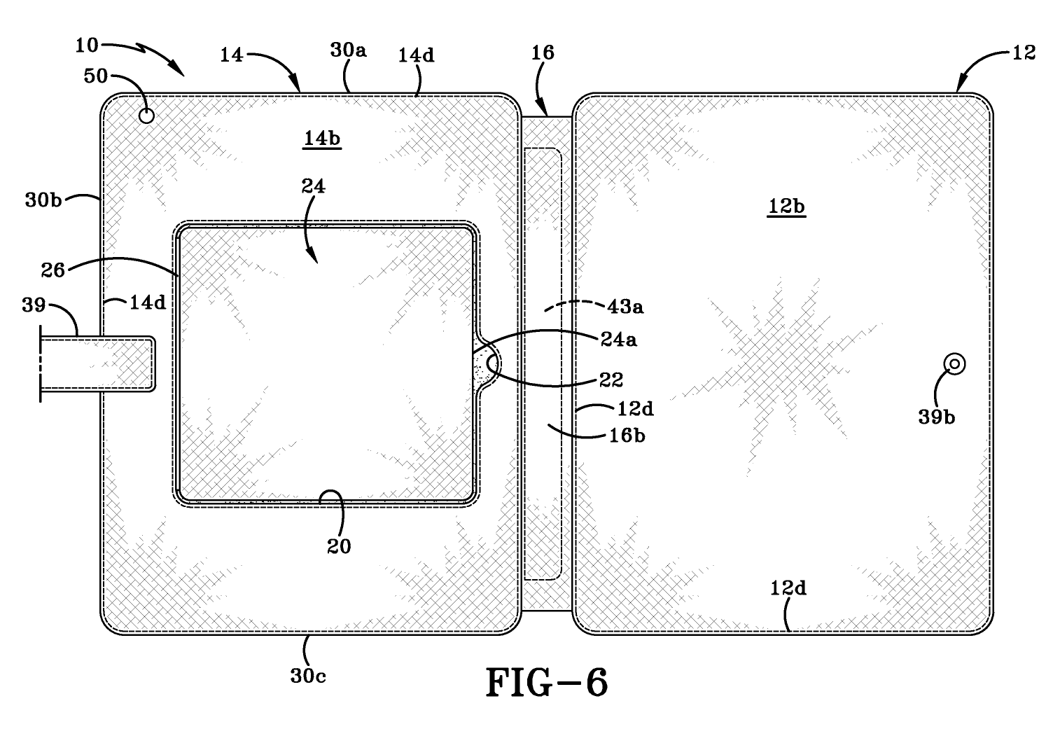

As indicated above, front 12 includes an interior layer 12a and exterior layer 12b. One or more additional layers of material, such as layers 12c (FIG. 7), are disposed between interior and exterior layers 12a, 12b. Preferably, each of interior and exterior layers 12a, 12b is comprised of a material such as leather. Layers 12c preferably include one layer of a rigid or stiff material and one or more layers of padding material. Interior and exterior layers 12a, 12b, and layers 12c preferably are secured together along their peripheral edges in any suitable manner, such as by stitching 12d (FIG. 7).

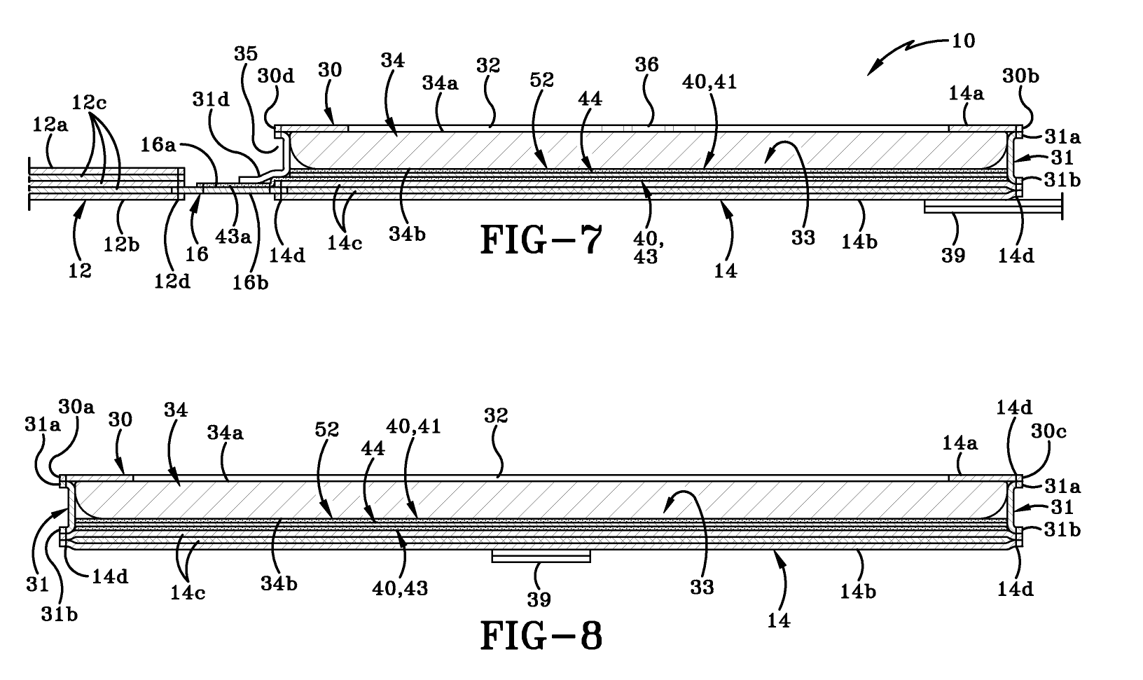

Similarly, as indicated above, back 14 includes an interior layer 14a, an exterior layer 14b. Back 14 further includes one or more additional layers 14c. Layers 14c preferably include one layer of a rigid or stiff material and one or more layers of padding material. Exterior layer 14b and layers 14c preferably are secured together along their peripheral edges in a suitable manner, such as by stitching 14d (FIG. 8). Interior and exterior layers 14a, 14b preferably are fabricated from the same material as interior and exterior layers 12a, 12b. So, in this particular instance, interior and exterior layers 14a, 14b preferably are fabricated from leather.

In accordance with a specific feature of the present invention, interior layer 14a is spaced a distance away from exterior layer 14b and the one or more layers 14c. Thus, a gap 35 (FIG. 7) is defined between interior layer 14a and layers 14c. Furthermore, the peripheral edge of interior layer 14a is not directly secured to the peripheral edges of exterior layer 14b and layers 14c. Instead, a plurality of strips 31 of material extends between interior layer 14a and the layers 14b, 14c. A first edge 31a of each strip 31 is fixedly secured to interior layer 14a, such as by stitching; and a second edge 31b of each strip 31 is fixedly secured to the connected layers 14b, 14c, The strips 31 are spaced a distance away from each other around most of the peripheral edge of interior layer 14a. The exception to this is the region of the peripheral edge of interior layer 14a that is disposed parallel and adjacent to spine 16. Openings (not numbered) are defined between adjacent strips 31.

Spine 16 comprises at least one layer of material that has an interior surface 16a and an exterior surface 16b. Preferably, as shown in FIG. 7, the at least one layer of spine 16 is a continuation of at least one of the layers 12c and 14c. In other words, at least one layer of material extends across all of the front 12, spine 16 and back 14 of case 10. Alternatively, spine 16 may be comprised of a separate elongate length of material, such as leather, that is secured to one or more layers of front 12 and back 14.

Front 12 includes one or more layers of material that are connected to interior layer 12a along three edges and which form pockets 18 on interior layer 12a. Pockets 18 are suitable for retaining papers and the like for safekeeping.

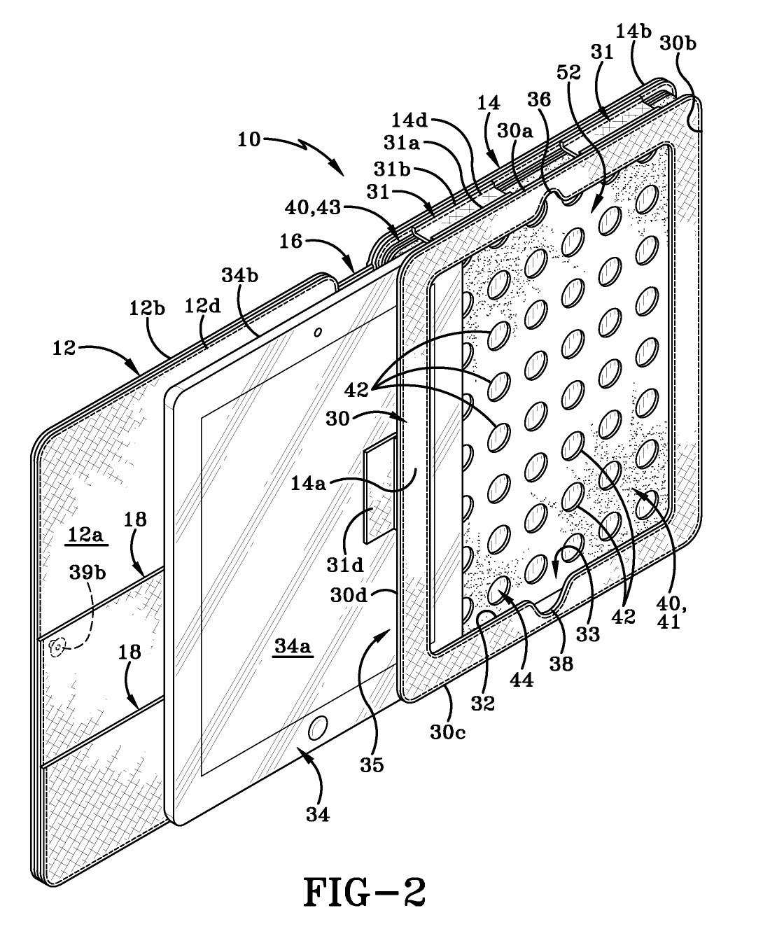

In accordance with a specific feature of the present invention, interior layer 14a of back 14 defines an aperture 32 therein. Aperture 32 is generally rectangular in shape and spaced a distance from the peripheral edge of interior layer 14a. Thus, interior layer 14a effectively forms a frame 30 around aperture 32. Frame 30 bounds and defines aperture 32. The first edge of frame 30 is identified by the reference character 30a, the second edge by the reference character 30b, the third edge by the reference character 30c, and the fourth edge by the reference character 30d. A single strip 31d is provided along fourth edge 30d of frame 30. Strip 31d is fixedly secured by stitching to interior layer 14a and an interior portion of this strip (i.e., the opposite surface to the one visible in FIG. 2) is provided with one of a hook and loop fastener fabric thereon. The purpose of this strip 31d will be discussed later herein. The configuration of back 14 and particularly frame member 30 and exterior layer 14b, causes a pocket 33 to be defined between exterior layer 14b and frame member 30. Since frame member 30 is not secured to exterior layer 14b along fourth edge 30d, pocket 33 is able to be accessed through an opening between fourth edge 30d and exterior layer 14b. Pocket 33 is suitably shaped and sized to receive an electronic device 34 therein. The user is able to insert electronic device 34 into pocket 33 through the opening between fourth edge 30d and exterior layer 14b. Preferably, as disclosed herein fourth edge 30d is disposed adjacent spine 16 so that electronic device 34 will not accidentally slide out of pocket 33 since spine 16 and front 12 close off access to the opening to pocket 33. Additionally, as will be described herein, strip 31d is temporarily securable to a portion of spine to retain electronic device 34 in pocket 33. It will be understood that air is able to flow through the openings (not numbered) between strips 31 and into pocket 33, thereby aiding in the cooling of electronic device 34 when it is in operation. Additionally, power cords and the like may be inserted through any appropriate opening and be connected to electronic device 34 to connect the same to a remote power source.

Aperture 32 defined by frame member 30 is configured to be sufficiently large enough so that substantially the entire screen 34a of electronic device 34 is able to be seen therethrough as is shown in FIG. 1. Frame member 30 further defines first and second recessed regions 36, 38 that are substantially continuous with aperture 32 and permit access to controls or components of electronic device 34 therethrough.

A closure member 39 is provided to secure front 12 and back 14 together when the interior layers 12a, 14a thereof are disposed adjacent each other. Closure member 39 comprises a strap that is fixedly secured at one end to exterior surface 14b of back 14; and mating snap-connectors 39a (on the strap) and 39b (on exterior surface 12b of front 12). When case 10 is moved to a closed position and the snap-connectors 39a, 39b are engaged, closure member 39 ensures that front 12 and back 14 are not able to move away from each other until the user is ready to operate electronic device. In this way, front 12 is kept in a position where it covers and therefore protects screen 34a. Additionally, electronic device 34 is prevented from accidentally sliding out of pocket 33.

In accordance with yet another feature of case 10, an opening 20 is defined in back 14. Opening 20 extends through exterior layer 14b and layers 14c and is therefore configured to be in fluid communication with pocket 33. Opening may be of any desired shape and size, such as the generally square shape shown in FIG. 6. Opening 20 is substantially continuous with pocket 33. A smaller, semi-circular recessed region 22 that is continuous with opening 20 is also defined in exterior layer 14b and layers 14c of back 14. A flap 24 is secured to exterior layer 14b of back 14 by way of a hinge 26. Hinge 26 joins one edge of flap 24 to a portion of exterior layer 14b adjacent opening 20. Recessed region 22 preferably is located opposite hinge 26 and provides a place for a user to insert a fingertip in order to engage a first edge 24a of flap 24 and to thereby move the same out of alignment with exterior layer 14b. Flap 24 is rotatable away from exterior layer 14b and into an open position to allow air to flow through opening toward or away from pocket 33. Flap 24 is rotated towards exterior layer 14b and into a closed position to limit air flow into and out of pocket 33 through opening 20.

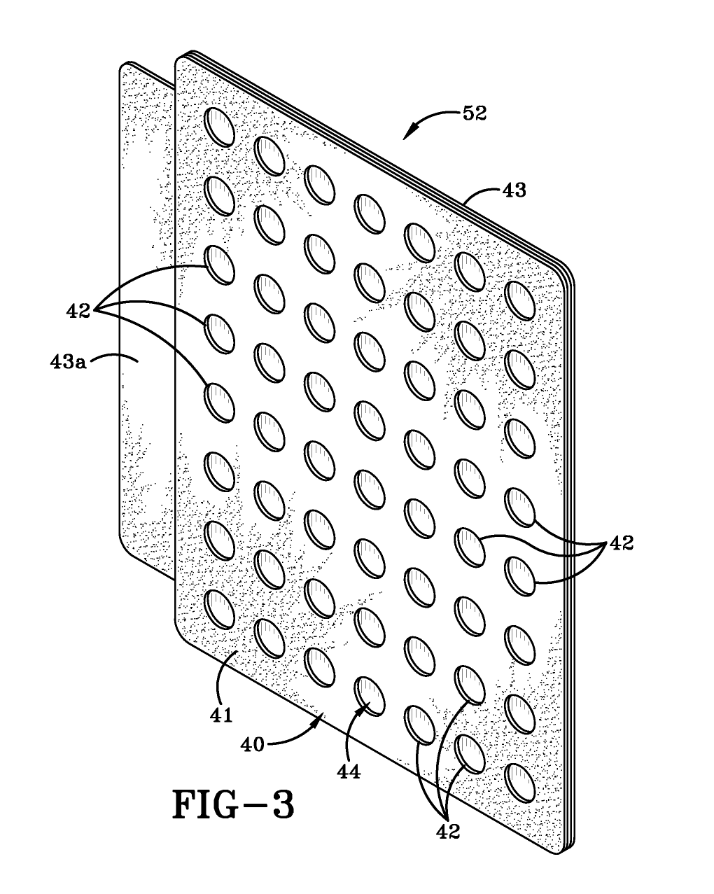

In accordance with a specific feature of the present invention, protective case 10 further includes a heat dissipation assembly 52 (FIG. 3). Heat dissipation assembly 52 is inserted into pocket 33 of case 10 and is positioned so that one side thereof is adjacent layers 14c of back 14. The other side of heat dissipation assembly 52 is positioned to be adjacent the rear surface 34b (FIG. 7) of electronic device 34 when the device 34 is received in pocket 33.

Heat dissipation assembly 52 comprises a sleeve 40 and a heat dissipation member 44 that is retained within sleeve 40. Sleeve 40 include a first layer 41 and a second layer 43 that are secured together so as to form a pocket (not shown) into which heat dissipation member 44 is received. Sleeve 40 preferably is fabricated from a mesh type of material. One of the layers 43 includes a region 43a that extends outwardly beyond a side edge of layer 41. This region 43a is sized to be received along spine 16 when heat dissipation assembly 52 is inserted into pocket 33 of case 10. Region 43a may be fixedly secured to interior surface 16a of spine 16 or may be temporarily secured thereto by hook and loop fasteners, for example. Preferably, a surface of region 43a that is disposed away from interior surface 16a is also provided with a hook and loop fastener that is matingly engageable with the hook and loop fastener on strip 31d.

In accordance with a specific feature of the present invention, each layer 41, 43 of sleeve 40 defines one or more apertures therein which extend between an interior surface and an exterior surface of the respective layer 41, 43. Preferably, each layer 41, 43 defines a plurality apertures 42 therein. Still further, each aperture 42 in layer 41 preferably is aligned with an aperture 42 in layer 43. The aligned pairs of apertures 42 provide a plurality of through holes in sleeve 40. Apertures 42 are defined at intervals in layers 41, 43, preferably in a geometric pattern such as the rows and columns illustrated in FIG. 3. It will be understood however that other patterns of apertures 42 may be utilized without departing from the scope of the present invention. Apertures 42 are at least positioned in an area of sleeve 40 that is most suitable to dissipate heat from an exhaust vent on electronic device 34.

Heat dissipation member 44 preferably comprises a planar sheet of a heat conductive material that is suitable for conducting heat that is generated by electronic device 34 away therefrom. Suitable materials that may be used for this purpose include a wide array of metallic substances. Most particularly, such substances preferably are highly heat conductive. One particularly suitable material for this purpose is a planar copper sheet. It will be understood that the heat dissipation member 44 may be made from materials other than metal and may instead be comprised of materials which are actively cooled by internal mechanisms, either physical or chemical in nature, and thereby are able to draw away heat generated by electronic device 34.

During fabrication of heat dissipation assembly, the sheet of copper is inserted into the pocket of the sleeve 40 and access to that pocket is then closed so that the copper sheet 44 cannot slide out of the same. When heat dissipation assembly is inserted into pocket 33 of case 10, apertures 42 in layer 41 of sleeve 40 are in fluid communication with pocket 33 and will therefore be disposed adjacent rear surface 34b of electronic device 34. Apertures 42 in layer 43 of sleeve 40 will be in fluid communication with opening 20. The heat dissipation member 44 is thus positioned between the apertures 42 in layer 41 and the apertures 42 in layer 43. The fabric of sleeve 40 (i.e., from which layers 41 and 43 are fabricated) provides an insulating layer between rear surface 34b of electronic device 34 and copper sheet 44. Otherwise, heat transferred from electronic device 34 would simply flow into copper sheet 44 and then be transmitted to all regions of rear surface 34b of electronic device 34 instead of being removed therefrom. The heat from electronic device 34 will instead heat up the air in apertures 42 adjacent rear surface 34b; that heat will heat up copper sheet 44 which in turn will heat up air in apertures 42 adjacent opening 20. Thus heat from electronic device 34 will be transmitted to the outside air through opening. Since copper is a far superior transmitter of heat than is air, the heat will be more rapidly dissipated from electronic device than would be the case if the copper sheet 44 was not provided.

Referring to FIG. 9, a strap 46 is secured at a first end to an exterior surface of sleeve 40 and at a second end to an interior surface of flap 24. A securement member 48a is provided on strap 46 and a mating securement member 48b is provided on flap 24. Securement members 48a, 48b snap-fittingly engage each other to enable the user to lock flap 24 in the closed position when desired (FIG. 6). A user will insert a fingertip into recess 22 and exert sufficient force to separate the engaged securement members 48a, 48b, and then rotate flap 24 into the open position (FIG. 9). Strap 46 limits the degree to which flap 24 may be rotated away from exterior layer 14b of back 14. This enables flap 24 to be moved to the open position and then be used as a support for retaining case 10 at an angle on a flat surface in conjunction with back 14. Thus, flap 24 is able to aid in supporting case 10 in much the same way as a picture frame is supported in a standing position on a surface. This feature allows the user to set the case 10 and electronic device 34 on a flat surface spaced a distance from them so that the user can watch a video on electronic device 34, for example. The positioning of case 10 at an angle to a flat surface also ensures that air can freely circulate around case 10 and more efficiently cool electronic device 34.

FIG. 6 shows that back 14 further defines a hole 50 therein. Hole 50 is provided in a location that is configured to align with a camera in a rear surface 34a of electronic device 34. It will be understood that the location of hole 50 will differ for different brands of electronic device. Thus, the positioning of hole 50 on protective case 10 may be in exterior layer 14b of back or on interior layer 14a thereof.

The device of the present invention is used in the following manner. The user disengages closure member 39 and rotates front 12 away from back 14 so that case 10 is in the open position shown in FIG. 2. The user inserts their electronic device 34 through the opening into pocket 33 and therefore between fourth edge 34d of frame member 30 and sleeve 40 and so that screen 34a aligns with aperture 32. The user secures electronic device in pocket 33 by engaging strip 31d with region 43a of sleeve 40. The user opens flap 24 on back 14, as previously described, to expose a portion of sleeve 40, apertures 42 therein and a portion of heat dissipation member 44 to the air circulating around case 10.

The user is then able to use electronic device 34 and as they do so, heat generated by device 34 is transferred by radiation and conduction to heat dissipation member 44. The heat drawn away from electronic device 34 by heat dissipation member 44 then exits case 10 through apertures 42 and opening 20 and moves into the surrounding air. When the user is finished with electronic device 34, it is switched off. Front 12 and back 14 are rotated about spine 16 back into abutting contact with each other. Flap 24 is moved to a closed position by rotating it about hinge 26 back into contact with exterior layer 14b and so that it covers opening 20. Securement members 48a, 48b are engaged to lock flap 24 in this closed position. Closure member 39 is then utilized to lock front 12 and back 14 together in the closed position. It will be understood that opening 20 preferably is of a sufficient size that is large enough to dissipate sufficient heat away from the electronic device 34 retained within case 10 to enable it to operate safely.

FIG. 10 shows a second embodiment of a case in accordance with the present invention, generally indicated at 110. Case 110 is configured and functions in substantially the same manner as case 10 with the exception of the back 114. Thus, case 110 includes a front 112, a back 114 and a spine 116, where the front 112 and back 114 are retained in a closed position when desired by a closure member 139. The back 114 includes strips 131 which extend between an interior layer (not shown) of back 114 and an exterior layer 114b. The electronics case 134 is received between the interior layer and exterior layer 114b.

In accordance with a specific feature of the invention, case 110 defines two pairs of apertures 160 that extend through exterior layer 114b. A band 162 of heat conductive material extends through each pair of apertures 160 and into the interior of back 114. Preferably the band of heat conductive material is a metal band, most particularly a copper band. Although not illustrated herein it will be understood that a portion of each band 162 will be disposed adjacent the rear surface (equivalent of rear surface 34a) of electronic device 134. Heat generated by electronic device 134 will be transferred to that portion of the band 162 adjacent the electronic device and then through the band 162 to the region that is disposed outside of exterior layer 114b. The heat within the region of band 162 outside of exterior layer 114b will then dissipate into the air surrounding case.

The bands 162 may be provided instead of or in addition to heat dissipation assembly 52. If heat dissipation assembly 52 is not provided in case 114 and only bands 162 are present, cover 124 may still be moved into the open position as previously described and then air will flow through the opening (not numbered) and directly contact the rear surface of electronic device 134, This too will cause heat to be drawn away from electronic device 134. The inclusion of bands 162 is advantageous because the user can operate the electronic device on a flat surface with the flap 124 in a closed position but still have an effective means of removing heat generated by electronic device 134.

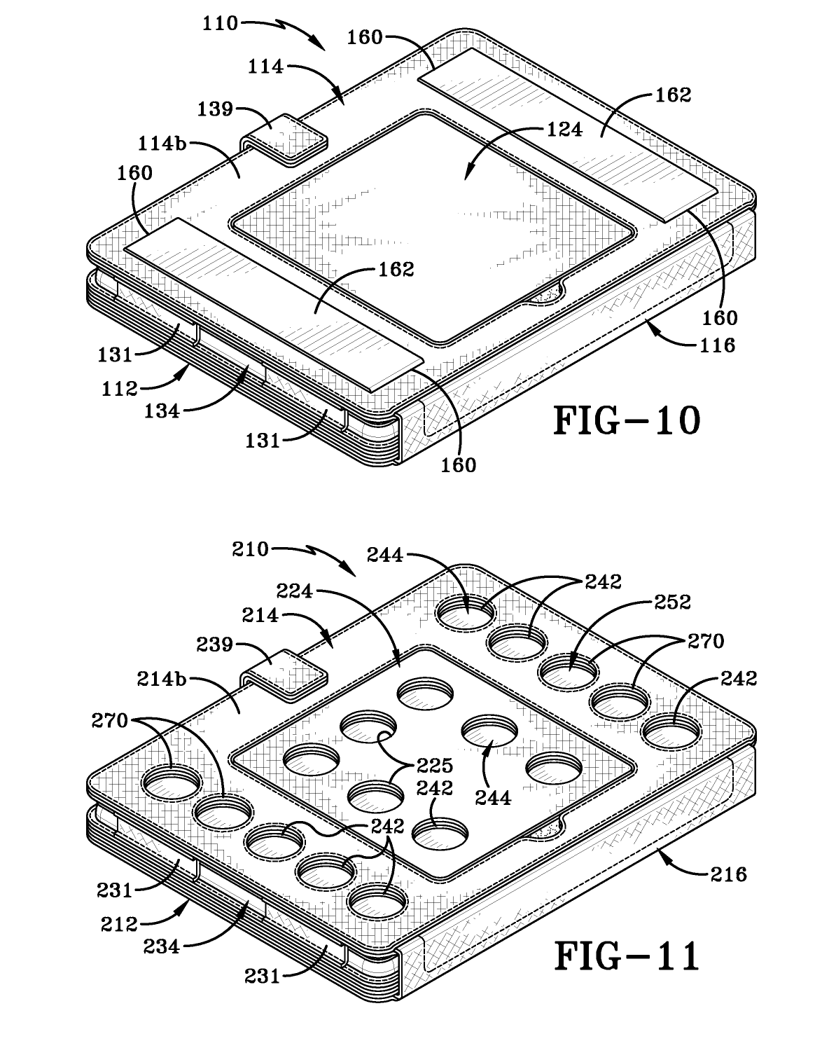

FIG. 11 shows a third embodiment of a case for an electronics device in accordance with the present invention, generally indicated at 210. Again, case 210 includes a front 212, a back 214, where the back 214 includes a pocket (not numbered) into which an electronic device 234 is receivable. Strips 231 keep electronic device 234 locked within the pocket but still allow air to flow through the gaps between strips 231 and into the pocket. A closure member 239 is provided to lock case when in a closed position. Back 214 devices an opening therein that is covered by a flap 224. A plurality of apertures 270 is defined in back 214 and a second plurality of apertures 225 is defined in flap 224. Apertures 225 and 270 align with apertures 242 defined in a sleeve 240 disposed within a pocket (not numbered) within case 210. A sheet of heat conductive material 244 (similar to heat dissipation member 44) is provided within sleeve 240. Heat generated by electronic device 234 is withdrawn therefrom by heat dissipation member 244 and then heat is lost from heat dissipation member 244 by contact with air flowing into the plurality of aligned apertures 242, 225, 270. This configuration again allows case 210 to protect electronic device while allowing heat to dissipate from the interior of case 210 when in a propped-up standing position (when flap 214 is rotated to an open position), or when flap 214 is in a closed position and case 210 lies flat on a surface.

It will be understood that alternatively, the heat dissipation member 252 may be omitted from the case. In that instance heat from electronic device 234 will exit case 210 through apertures 270. To further enhance the loss of heat from case 210, flap 224 may be propped into an open position as described previously with respect to flap 24.

Although not illustrated herein, it will be understood that case may alternatively be free of front 12 and comprise only the back 14 having an opening 20 defined therein and a pocket 33 for receiving the electronic device, where the pocket retains a includes heat dissipation member 52 therein. The back 14 would protect the back and sides of the electronic device 34 but would leave screen 34a exposed. In this instance some type of retaining member would be needed to secure electronic device 34 within pocket 33 along fourth edge 30d. In this embodiment of the case, the heat dissipation member 44 retained within the back 14 would more efficiently remove heat from electronic device 34 than if the electronic device were not retained within the case. The reason for this is that metal conducts heat from one location to another far more efficiently than does air. Not only would this version of the case assist in heat reduction but the case would provide protection to the back and sides of the electronic article and thereby reduce the possibility that the device would be damaged by impact.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of the invention are an example and the invention is not limited to the exact details shown or described.

1. A protective case for a planar electronic device, said cover comprising:
a back having an interior surface and an exterior surface;
an opening defined in the exterior surface of the back;
a pocket defined in the back between the interior and exterior surfaces, and wherein said pocket is adapted to receive the electronic device therein; and
a heat dissipating assembly disposed adjacent the opening; said heat dissipating assembly being adapted to draw heat from the electronic device and transmit the heat to air surrounding the back.

2. The protective case as defined in claim 1, wherein the heat dissipating assembly is received within the pocket in the back and extends across the opening.

3. The protective case as defined in claim 1, wherein at least a portion of the heat dissipating assembly extends outwardly from the back through the opening and is disposed for a distance adjacent an exterior surface of the back.

4. The protective case as defined in claim 3, wherein the portion of the heat dissipating assembly comprises a copper band that extends for a distance across the back of the case.

5. The protective case as defined in claim 4, further comprising a second opening spaced a distance from the opening, and wherein the copper band extends inwardly into the pocket.

6. The protective case as defined in claim 5, further comprising:
a pair of additional openings disposed a spaced distance from the opening and second opening; and
a second copper band extending outwardly from the pocket through one of the pair of additional openings, extending for a distance across an exterior surface of the back and extending inwardly into the pocket through the other of the pair of additional openings.

7. The protective case as defined in claim 2, wherein the heat dissipating assembly includes:
a sleeve having a first and second layer; and
a heat dissipating member disposed between the first and second layers.

8. The protective case as defined in claim 7, further comprising one or more apertures defined in the first layer of the sleeve and extending between an interior surface and exterior surface of the first layer; and
one or more apertures defined in the second layer of the sleeve and extending between an interior surface and exterior surface of the second layer.

9. The protective case as defined in claim 8, wherein the one or more apertures in the first layer are aligned with the one or more apertures in the second layer.

10. The protective case as defined in claim 9, further comprising one or more apertures defined in an exterior surface of the back; and wherein the one or more apertures in the back are aligned with the aligned one or more apertures in the first and second layers of the sleeve.

11. The protective case as defined in claim 10, further comprising a flap which selectively extends across the opening in the back; and one or more additional apertures are defined in the flap; and wherein the one or more additional apertures in the flap are aligned with one or more apertures in the first and second layers of the sleeve.

12. The protective case as defined in claim 7; wherein the heat dissipation member comprises a sheet of a heat conductive material.

13. The protective case as defined in claim 12, wherein the sheet of heat conductive material is a sheet of metal.

14. The protective case as defined in claim 13, wherein the sheet of metal is a sheet of copper.

15. The protective case as defined in claim 1, further comprising:
a flap which is engaged with back and is selectively positionable over the opening; said flap being rotatable between an open position where access to the opening is permitted; and a closed position where access to the opening is substantially prevented.

16. The protective case as defined in claim 15, further comprising a strap having a first end that is engaged with the flap and a second end that is engaged with the heat dissipation assembly.

17. The protective case as defined in claim 1, further comprising:
a front;
a spine connecting the front to the back; and wherein the spine folds to bring an interior region of the front into a position adjacent an interior region of the back; and wherein the case is movable between an open position where the interior region of the front is remote from the interior region of the back; and a closed position where the interior regions are adjacent each other.

18. The protective case as defined in claim 17, further comprising a closure member that is fixedly secured to one of the front and back and is selectively engageable with the other of the front and back; and wherein the closure member is engaged to retain the case in the closed position.

19. A method of dissipating heat from an electronic device comprising the steps of:
placing the electronic device into a pocket of a protective case;
positioning the electronic device adjacent a portion of a heat dissipation assembly disposed within the pocket;
activating the electronic device and thereby generating heat;
drawing the generated heat away from the electronic device via the heat dissipation assembly; and
transferring the heat through the heat dissipation assembly and through an opening in region of the protective case.

20. The method as defined in claim 19, wherein the step of positioning the electronic device adjacent a portion of heat dissipation assembly includes positioning a rear surface of the electronic device adjacent a sheet of heat conductive material.

21. The method as defined in claim 20, wherein the step of positioning the rear surface of the electronic device includes the steps of:
placing a copper sheet inside a fabric sleeve having a plurality of apertures therein;
inserting the sleeve and copper sheet inside a pocket within the electronic case;
placing the rear surface of the electronic sheet adjacent a layer of the fabric sleeve which includes the apertures.
